(19) United States
(12) Patent Application Publication
(10) Pub. No.: US 2015/0243484 A1
(43) Pub. Date: Aug. 27, 2015

(54) Plasma Source

(71) Applicant: GENCOA LTD, Liverpool (GB)

(72) Inventor: Victor Bellido-Gonzalez, Liverpool (GB)

(21) Appl. No.: 14/427,579

(22) PCT Filed: Sep. 11, 2013
(86) PCT No.: PCT/GB13/52372

§ 371 Date: Mar. 11, 2015

(30) Foreign Application Priority Data
Sep. 11, 2012 (GB) 1216138.6

(51) Int. Cl. H01J 37/32; C23C 16/50; C23C 14/22; H01J 37/34

(52) U.S. Cl. CPC H01J 37/3266; H01J 37/32055; H01J 37/32651; H01J 37/3405; C23C 16/50; C23C 14/22; H01J 2237/332

(57) ABSTRACT

This invention relates to magnetically enhanced cathodic plasma deposition and cathodic plasma discharges where the charged particles can be guided in a rarefied vacuum system. Specifically, a cluster or combination of cathodic plasma sources is described where a least two plasma source units are arranged in a rarefied gas vacuum system in such way that the resulting magnetic field interaction offers a guided channelling escape path of electrons in essentially perpendicular direction to the main bulk of neutral particles and droplets generated in the cathodic plasma source. In addition the cathodic plasma source arrangement of the present invention would generate a zone of very low magnetic field where the electrons are trapped via electric and magnetic fields. Ions generated by the plasma cluster would follow electrons via escape paths determined by electric and magnetic fields. The direction for the ions is fundamentally different from those of the neutral particles offering in this manner a charged particles filtering method. The invention could take form in different embodiments and different arrangements of these plasma clusters, interacting by magnetic interactions in such a way that the plasma would cross areas for the desired plasma treatment and/or coating of suitable substrates.

This invention relates to magnetically enhanced cathodic plasma deposition and cathodic plasma discharges where the charged particles can be guided in a rarefied vacuum system.

In vacuum deposition processes, such as PVD and PACVD, an arc source can be used to form a plasma. It is usually necessary to provide an electrical and a magnetic field to shape and direct the ions forming the plasma so that they are preferentially located in certain regions of the process chamber, for example, adjacent a substrate to be coated or treated.

Arcs are formed on the cathode surface. These arcs are plasmas in themselves which would vaporise material from the source's target which is part of the cathode Particles and electrons are released from the cathode and the collisions on the vapour phase would produce ions. these ions respond to the electric field generated by the plasma itself. I It is often desirable to jet the plasma away from the target surface and such ejected plasma can be used in the process chamber. Such a configuration results in a steady supply of ionised particles.

The ejection of plasma away from the arc source can be achieved by providing a magnetic field, which guides the electrons, subsequently the ions would follow the electrons driven by the generated electric field force as the electros depart the cathode vicinity towards the process area. Controlling the magnetic field in a predictable and desirable manner poses a particular challenge to vacuum process equipment designers. Various magnetic arrangements have been proposed and this invention relates to an improved and/or an alternative arrangement for controlling the ejection of a plasma from a plasma source.

According to a first aspect of the invention there is provided a plasma source comprising: a first and a second, spaced-apart plasma source unit each plasma source unit comprising a target and a magnetic means; wherein the magnetic means each create a magnetic field which forms a closed loop magnetic trap over their respective targets; and which fields interact to form: an area of substantially very low magnetic field strength in a region located between the plasma sources; and a guiding magnetic field extending away from the region located between the plasma source units.

The target is suitably a consumable target, which can be manufactured from a material that is vaporised to form a vapour, which, when ionised, forms a plasma.

The target is suitably located adjacent to the magnetic means. The target can comprise a block of consumable material, which can be fixed relative to the magnetic means. Additionally or alternatively, the target can comprise a tubular target arranged to surround the magnetic means. Suitably, a tubular target can be arranged to rotate about the magnetic means so that the target is consumed, on average, more evenly over time. The speed and direction of the rotation of the target can be varied to suit different process requirements.

The first and a second plasma source units each comprise a magnetic means, whose polarities are suitably selected to oppose one another, for example, with their North poles facing one another (or aligned in the same direction), or with their South poles facing one another (or aligned in the same direction). Such a configuration can create a magnetic repulsion or a magnetic attraction, which, in the region between the plasma sources, cancel one another out, to crate the area of substantially very low magnetic field strength in the region located between the plasma sources.

The magnetic means suitably comprises a magnet or a group of magnets. The magnet or magnets can be permanent magnets and/or electromagnets. The magnet or magnets of each plasma source unit suitably set up a magnetic field that can be represented by magnetic field lines that intersect the target at spaced apart locations, but which curve away from the target to form the closed-loop magnetic trap or traps.

The magnetic fields of the plasma source units suitably interact and can be represented by magnetic field lines that extending outwardly from the targets and away from the region located between the plasma source units. Such a magnetic field forms the channel, which is a region (volume) of relatively low magnetic field strength, which poses little resistance to the flow of ions within the plasma. The channel or channels thus provide a “path of least resistance”, which encourages the plasma to be ejected in a preferential direction or directions corresponding to the channels.

In certain embodiments, the plasma source units are arranged in direct opposition, that is to say, facing each other and arranged substantially symmetrically about a perpendicular line extending through the channel. However, the plasma source units may be inclined relative to one another to create a bias such that the plasma is ejected preferentially from one side of the source.

Any number of plasma source units may be provided. In certain embodiments, there are three plasma source units arranged in a U shape, such that the magnetic fields interact with one another to form a single channel extending outwardly from the open part of the U.

A surface may be provided to one side of a pair of plasma source units to form a U-shape, such that the surface and magnetic fields of the plasma source units interact to form a single channel extending outwardly from the open part of the U. The surface may be in contact with, or integrally formed with one or more of the magnetic means. The surface may be electrically biased relative to the magnetic means.

According to a second aspect of the invention a cluster or combination of cathodic plasma sources is provided where a least 2 plasma source units are arranged in a rarefied gas vacuum system in such way that the resulting magnetic field interaction offers a guided channelling escape path of electrons in essentially perpendicular direction to the main bulk of neutral particles and droplets generated in the cathodic plasma source. In addition the cathodic plasma source arrangement of the present invention would generate a zone of very low magnetic field where the electrons are trapped via electric and magnetic fields. In the present invention, at least one of the cathodic plasma sources would generate positively charged particles via suitable collisions between energetic electrons and neutrals, or by intense power density discharges on the surface or near surface of a target material, or by any other phenomena or combination of phenomena which gives as a result ionisation. Ions could be generated from elements of the target or from elements of the rarefied gas. Ions could also be generated by arc phenomena on the target surface or by a high power pulsed energy wave. In the present invention at least one of the cathodic plasma sources would have a closed loop magnetic field trap. This magnetic field trap is essentially placed over the target surface, and in that way it would be trapping plasma over the target surface. In this trap a magnetron is formed, that is, an area of substantial perpendicularity between the electric field and the magnetic field is present. This area would induce the area of higher target plasma activity, as the electric field and the magnetic field are essentially perpendicular to each other. The plasma escape routes of one of the embodiments of the present invention is parallel to two facing targets whist most of the non charged particles travel in its majority on a different direction.

In another embodiment of the present invention, the plasma cluster is form by a surface with substantial negative bias which is placed in the vicinity of the 2 cathodic plasma units in such a way that one of the perpendicular escape routes is blocked. As the electrons are repelled, hence a single escape route for the electrons is established.

In another embodiment of the present invention the plasma cluster is formed by substantially negatively biased surface that could be at the same potential as the 2 facing cathodic plasma sources, alternatively the additional surface could be an electrically insulated component, or even a 3^{rd} plasma source similar or different in nature to the 2 facing cathodic plasma sources.

In another part of the present invention an array of any number of the above described clusters could be used within the same vacuum system.

The energy delivery system powering these plasma sources could be of different nature, DC, pulsed DC. It could also be AC at low (1-100s of Hertz), medium (kHz) or high (MHz) frequencies. High power pulses could also be used in order to power the cathodic plasma sources. The power could be coupled in different ways, for example the embodiments would operate mainly as cathodes or as alternating cathode/anode. Additional anodes could also be added into the vacuum system in order to direct the electrons discharge from the plasma sources to the anodes placed at specific location. The anode location could be static or dynamic. There could be a plurality of anodes at the same of different potential. There could be a plurality of plasma sources static or dynamic.

The cathodic plasma sources as an example could be in a substantial arc mode, magnetron sputtering mode, hollow cathode mode, diode mode, triode mode or any combination of those modes.

The cathodic plasma sources as an example could be in non reactive or reactive modes, where other elements or compounds are added into the vacuum system in order to produce chemical reactions in the plasma and substrate surfaces, such as the reaction of Ti and O₂ to form TiOx, or reaction with monomers producing polymers, or reaction of HMDSO and oxygen in order to produce a polysiloxane or SiOx coating, or any complex type of reaction.

A preferred arrangement of any plurality of plasma sources and anodes is such that the electron travelling path from the plasma cluster to the anodes or among the plasma clusters would cross in a substantial manner the area of substrates to be plasma treated or coated.

In the present invention any of the gases or vapour species added into the vacuum system could be introduced with or without a feedback control system. The feedback control system would actively control the reaction by monitoring the plasma and actuating on different process parameters such as gas and vapour feeds, power, anode potential as an example.

This invention also relates to the use of plasma clusters with anodes that also have magnetic elements for better guidance of electrons. The anode could have a ground or positive potential with respect to ground or the cluster cathodes.

The present invention relates to the use of the cluster plasma sources in different system application such as web, glass, display, decorative and batch coaters.

The invention will be further described by way of example only with reference to the following figure in which:

FIG. 1 is a schematic cross section of a first embodiment of the invention;

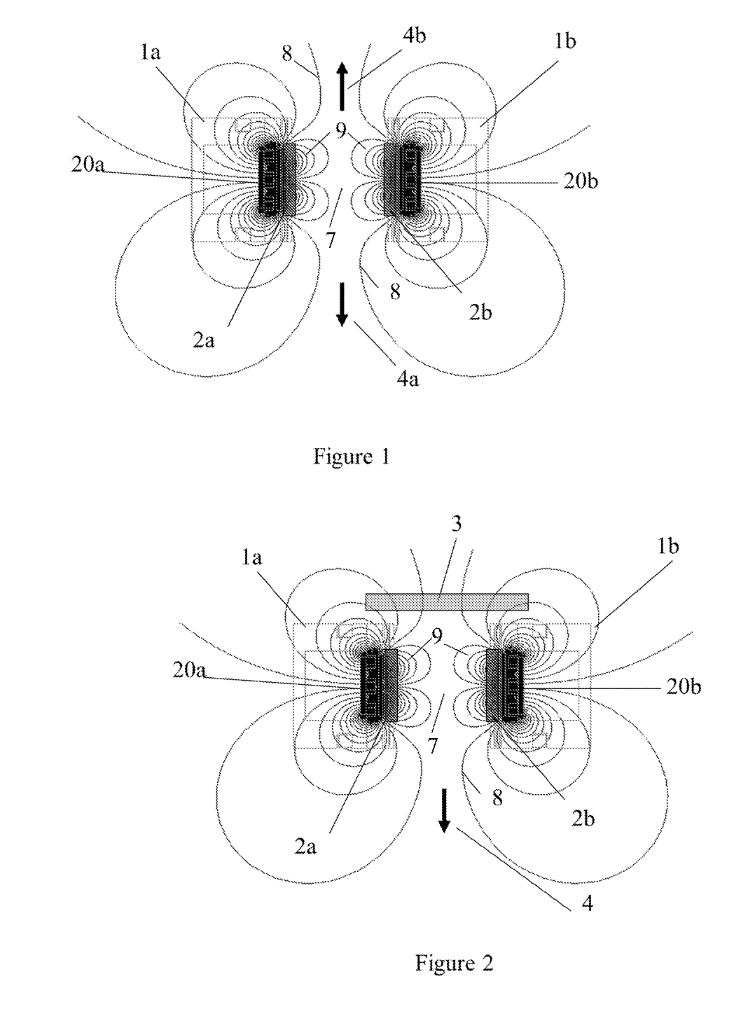

FIG. 2 is a schematic cross section of a second embodiment of the invention;

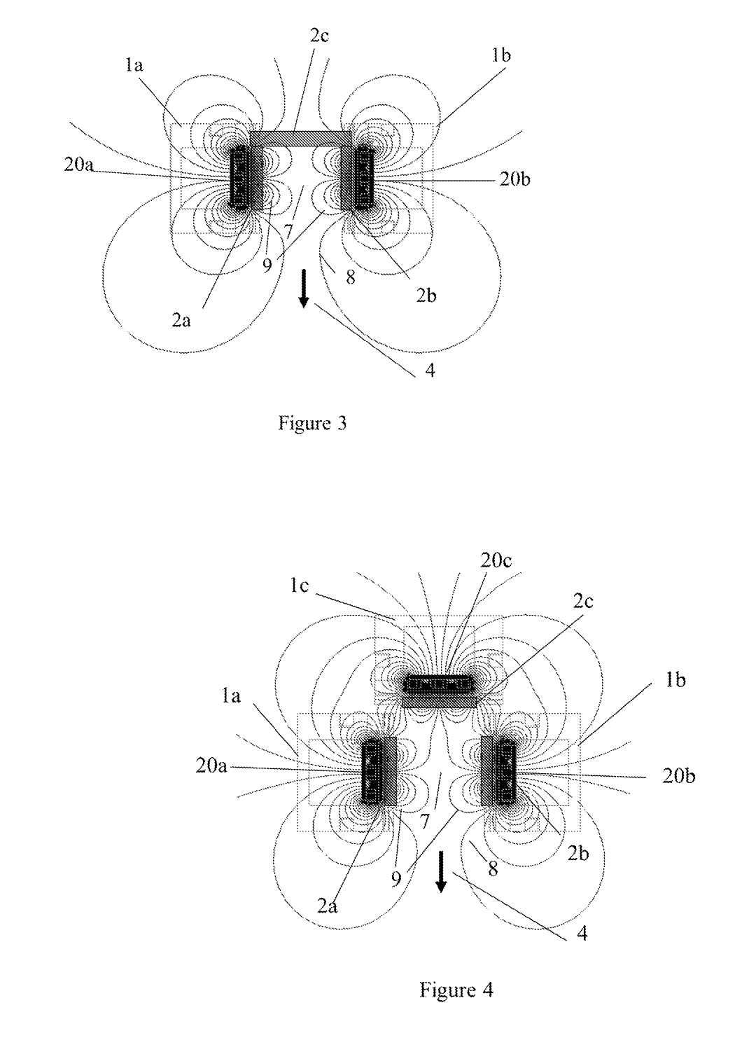

FIG. 3 is a schematic cross section of a third embodiment of the invention;

FIG. 4 is a schematic cross section of a fourth embodiment of the invention;

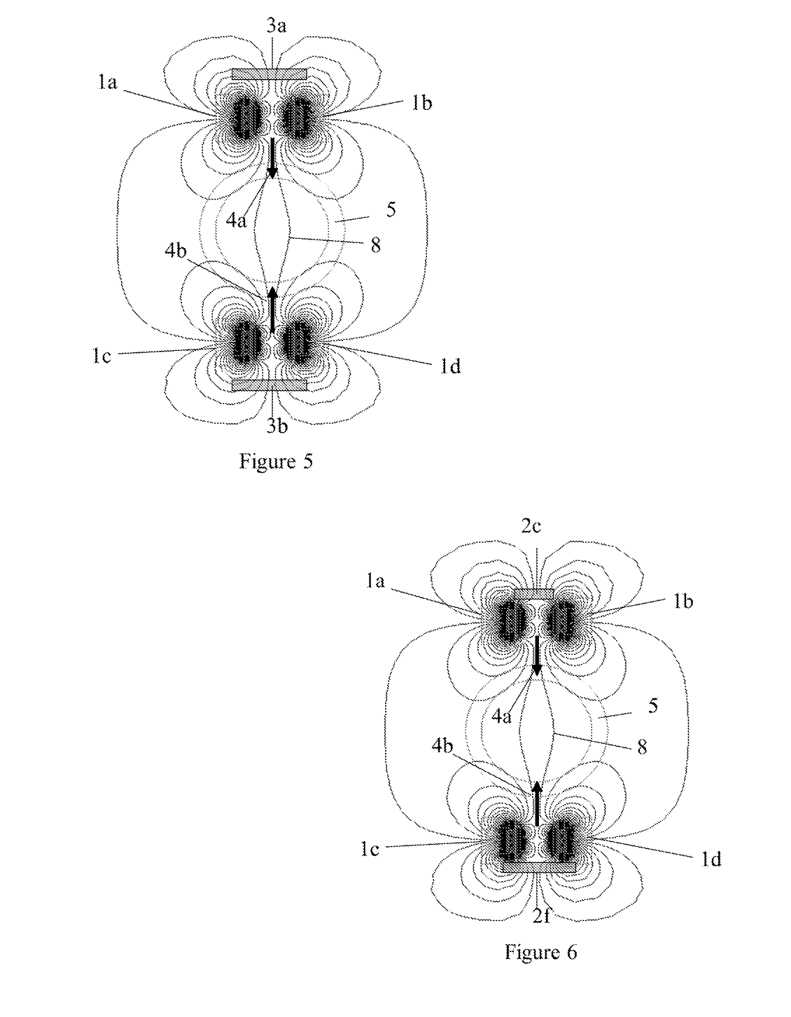

FIG. 5 is a schematic cross section of a fifth embodiment of the invention;

FIG. 6 is a schematic cross section of a sixth embodiment of the invention;

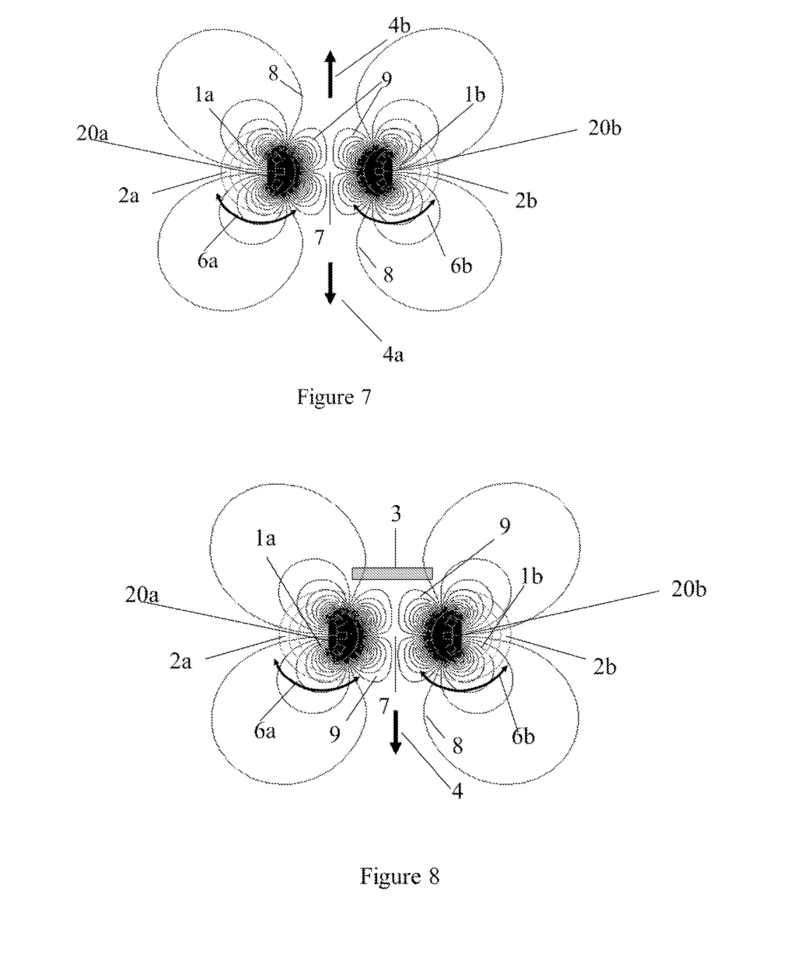

FIG. 7 is a schematic cross section of a seventh embodiment of the invention;

FIG. 8 is a schematic cross section of a eighth embodiment of the invention;

FIG. 8 is a schematic cross section of a ninth embodiment of the invention;

FIG. 10 is a schematic cross section of a tenth embodiment of the invention;

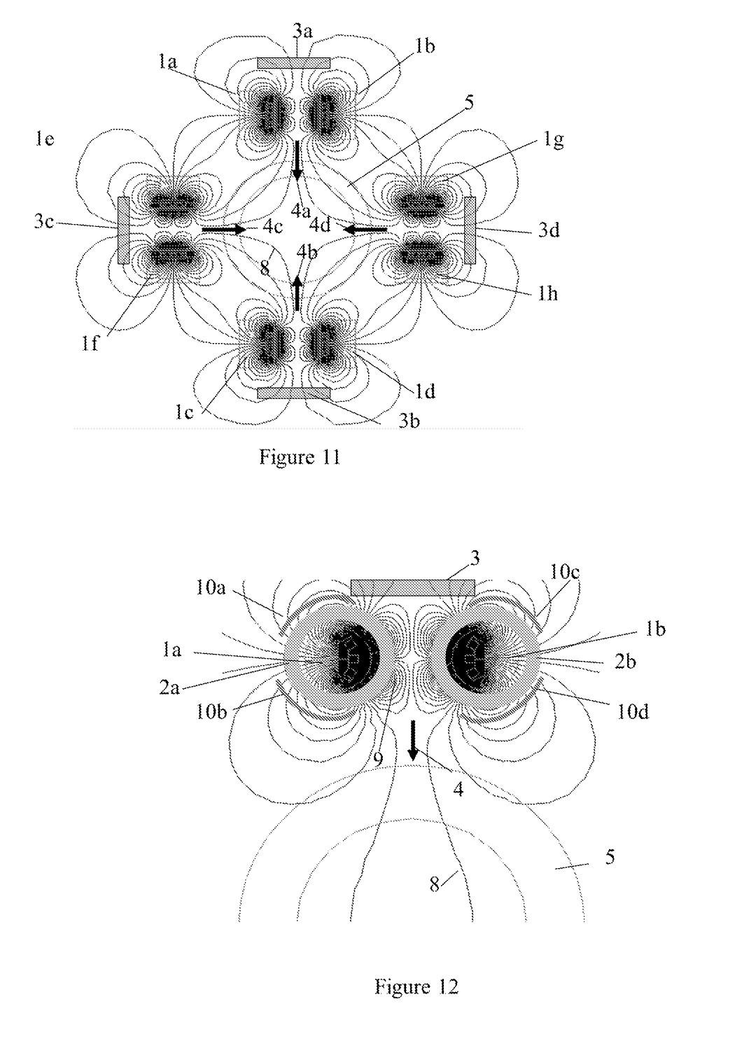

FIG. 11 is a schematic cross section of a eleventh embodiment of the invention;

FIG. 12 is a schematic cross section of a twelfth embodiment of the invention;

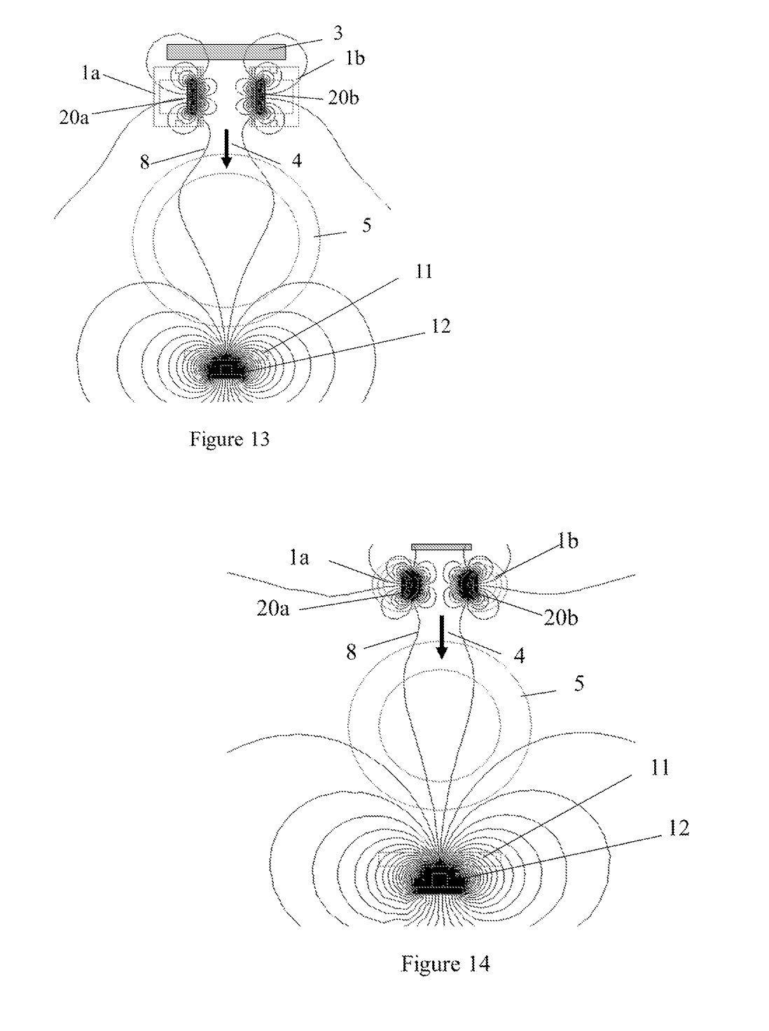

FIG. 13 is a schematic cross section of a thirteenth embodiment of the invention; and

FIG. 14 is a schematic cross section of a fourteenth embodiment of the invention.

FIG. 1 shows a cross section of a cluster plasma source, an embodiment of the present invention where two individual cathodic plasma sources, 1a and 1b, are arranged facing each other in an essentially parallel manner. The magnetic arrays 20a and 20b form a closed loop magnetic traps 9 over the respective target elements 2a and 2b. The magnetic polarity of the arrays 20a and 20b is such that an area of substantial very low magnetic field 7 is generated in between the two plasma sources and guiding magnetic field lines 8 form channels for the electron escape 4a and 4b. The electric field of the plasma discharge is such that the positively charged particles would follow the electrons along the escape paths 4a and 4b. In addition the units 1a and 1b or targets 2a and 2b could be in a non parallel orientation.

FIG. 2 shows a cross section of a cluster plasma source of the present invention where two individual cathodic plasma sources, 1a and 1b, are arranged facing each other in an essentially parallel manner. The magnetic arrays 20a and 20b form a closed loop magnetic traps 9 over the respective target elements 2a and 2b. The magnetic polarity of the arrays 20a and 20b is such that an area of substantial very low magnetic field 7 is generated in between the two plasma sources and guiding magnetic field lines 8 form channels for electron escape 4. The cluster also includes a surface 3 which is negatively biased either by external means or by self-biasing from the plasma. The effect of the surface 3 is to stop the electron escape with respect to the described cluster of FIG. 1. Hence the electric field of the plasma discharge is such that the positively charged particles would follow the electrons along the single escape path 4.

FIG. 3 shows a cross section of a cluster plasma source, an embodiment of the present invention where two individual cathodic plasma sources, 1a and 1b, are arranged facing each other in an essentially parallel manner. The magnetic arrays 20a and 20b form a closed loop magnetic traps 9 over the respective target elements 2a and 2b. The magnetic polarity of the arrays 20a and 20b is such that an area of substantial very low magnetic field 7 is generated in between the two plasma sources and guiding magnetic field lines 8 form channels for the electron escape 4. The cluster also includes a surface 2c which is either biased at the same potential as targets 2a and 2b or at a floating self-biased potential. As a result the electron escape is reduced to a single path 4. The electric field of the plasma discharge is such that the positively charged particles would follow the electrons along the single escape path 4.

FIG. 4 shows a cross section of a cluster plasma source, an embodiment of the present invention where three individual cathodic plasma sources, 1a, 1b and 1c are arranged so that two of the units 1a and 1b are facing each other in an essentially parallel manner. The 3^{rd} plasma source 1c is arranged in an essentially perpendicular position to plasma sources 1a and 1b. The magnetic arrays 20a, 20b and 20c form a closed loop magnetic traps 9 over the respective target elements 2a, 2b and 2c. The magnetic polarity of the arrays 20a, 20b and 20c is such that an area of substantial very low magnetic field 7 is generated in between the three plasma sources and guiding magnetic field lines 8 form channels for the electron escape 4. The electric field of the plasma discharge is such that the positively charged particles would follow the electrons along the single escape path 4.

FIG. 5 shows a cross section of a combination of plasma clusters in a vacuum deposition system. Each of the plasma clusters could be any of the embodiments described in previous FIGS. 1-4. As an example, using clusters embodiments as described in FIG. 2, the first plasma cluster embodiment is composed of cathodic plasma sources 1a, 1b and surface 3a biased in such a way that a single main electron escape path 4a is defined for this plasma cluster. The second plasma cluster embodiment is composed of cathodic plasma sources 1c, 1d and surface 3b, biased in such a way that a single main electron escape path 4b is defined for this plasma cluster. The magnetic polarities of the two clusters are such that the guiding magnetic field lines 8 link from one cluster to the other, establishing an area of plasma trap crossing through the substrate zone 5.

FIG. 6 shows a cross section of a combination of plasma clusters in a vacuum deposition system. Each of the plasma clusters could be any of the embodiments described in previous FIGS. 1-4. As an example, using clusters embodiments as described in FIG. 3, the first plasma cluster embodiment is composed of cathodic plasma sources 1a, 1b and surface 2c biased in such a way that a single main electron escape path 4a is defined for this plasma cluster. The second plasma cluster embodiment is composed of cathodic plasma sources 1c, 1d and surface 2f, biased in such a way that a single main electron escape path 4b is defined for this plasma cluster. The magnetic polarities of the two clusters are such that the guiding magnetic field lines 8 link from one cluster to the other, establishing an area of plasma trap crossing through the substrate zone 5.

FIG. 7 shows a cross section of a cluster plasma source, an embodiment of the present invention where two individual cathodic plasma sources, 1a and 1b, are arranged facing each other in an essentially parallel manner. The magnetic arrays 20a and 20b form a closed loop magnetic traps 9 over the respective target elements 2a and 2b. The target elements 2a and 2b have in this case a cylindrical form, and are intended, or though not necessarily have, to rotate in either direction 6a and 6b while the magnetic array 20a and 20b are essentially static. The magnetic polarity of the arrays 20a and 20b is such that an area of substantial very low magnetic field 7 is generated in between the two plasma sources and guiding magnetic field lines 8 form channels for the electron escape 4a and 4b. The electric field of the plasma discharge is such that the positively charged particles would follow the electrons along the escape paths 4a and 4b. In addition the units 1a and 1b or arrays 20a and 20b could be in a non parallel orientation, but forming a different angle with respect to escape paths 4a and 4b.

FIG. 8 shows a cross section of a cluster plasma source, an embodiment of the present invention where two individual cathodic plasma sources, 1a and 1b, are arranged facing each other in an essentially parallel manner together with a surface 3 in an essentially triangular position. The magnetic arrays 20a and 20b form a closed loop magnetic traps 9 over the respective target elements 2a and 2b. The target elements 2a and 2b have in this case a cylindrical form, and are intended, or though not necessarily have, to rotate in either direction 6a and 6b while the magnetic array 20a and 20b are essentially static. The magnetic polarity of the arrays 20a and 20b is such that an area of substantial very low magnetic field 7 is generated in between the two plasma sources and guiding magnetic field lines 8 form channels for the electron escape 4. Surface 3 would be negatively biased either by external means of by a self-bias induced by the plasma. The effect of the surface 3 is to stop the electron from escaping in one of the directions with respect to the described cluster of FIG. 7. Hence the electric field of the plasma discharge is such that the positively charged particles would follow the electrons along the single escape path 4

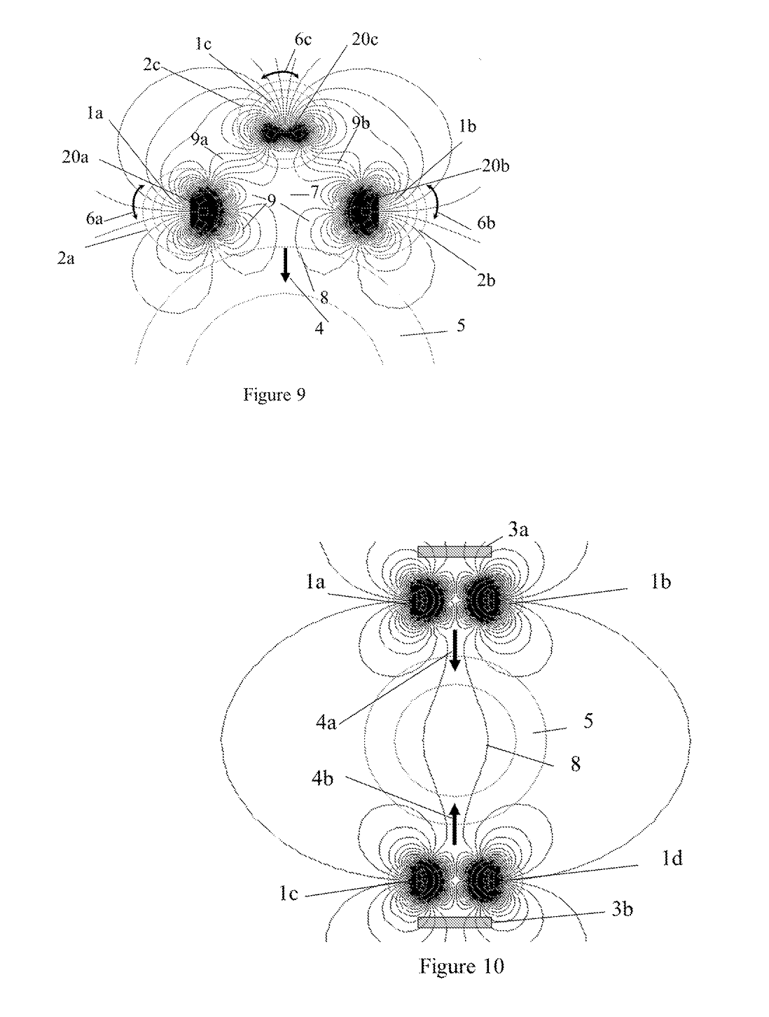

FIG. 9 shows a cross section of a cluster plasma source, an embodiment of the present invention where three individual cathodic plasma sources, 1a, 1b and 1c, which are arranged so that two of the units 1a and 1b are facing each other in an essentially parallel manner. The 3^{rd} plasma source 1c is arranged in a triangular position with respect to the other cathodic plasma sources 1a and 1b. The magnetic arrays 20a, and 20b form a closed loop magnetic traps 9 over the respective target elements 2a and 2b. The magnetic array 20c forms closed field lines with arrays 9a and 9b with arrays 20a and 20b respectively. The target elements 2a, 2b and 2c have in this case a cylindrical form, and are intended, or though not necessarily have, to rotate in either direction 6a, 6c and 6c while the magnetic arrays 20a, 20b and 20c are essentially static. In another embodiment of the present invention there could be any combination between planar and cylindrical targets 2a, 2b and 2c. The magnetic polarity of the arrays 20a, 20b and 20c is such that an area of substantial very low magnetic field 7 is generated in between the three plasma sources and guiding magnetic field lines 8 form channels for the electron escape 4. The single escape path 4 is in this manner guiding electrons across a substrate zone 5.

FIG. 10 shows a cross section of a combination of plasma clusters in a vacuum deposition system. Each of the plasma clusters could be any of the embodiments described in previous FIGS. 1-4 and 7-9. As an example, using 2 off clusters embodiments as described in FIG. 8, the first plasma cluster embodiment is composed of cathodic plasma sources 1a, 1b and surface 3a biased in such a way that a single main electron escape path 4a is defined for this plasma cluster. The second plasma cluster embodiment is composed of cathodic plasma sources 1c, 1d and surface 3b, biased in such a way that a single main electron escape path 4b is defined for this plasma cluster. The magnetic polarities of the two clusters is such that the guiding magnetic field lines 8 link from one cluster to the other, establishing an area of plasma trap crossing through the substrate zone 5.

FIG. 11 shows a cross section of a combination of plasma clusters in a vacuum deposition system. Each of the plasma clusters could be any of the embodiments described in previous FIGS. 1-4 and 7-9. As an example, using 4 off clusters embodiments as described in FIG. 2, the first plasma cluster embodiment is composed of cathodic plasma sources 1a, 1b and surface 3a biased in such a way that a single main electron escape path 4a is defined for this plasma cluster. The second plasma cluster embodiment is composed of cathodic plasma sources 1c, 1d and surface 3b, biased in such a way that a single main electron escape path 4b is defined for this plasma cluster. The third plasma cluster embodiment is composed of cathodic plasma sources 1e, 1f and surface 3c biased in such a way that a single main electron escape path 4c is defined for this plasma cluster. The forth plasma cluster embodiment is composed of cathodic plasma sources 1g, 1h and surface 3d, biased in such a way that a single main electron escape path 4d is defined for this plasma cluster. The magnetic polarities of the four plasma clusters are such that the guiding magnetic field lines 8 link from one cluster to the other, establishing an area of plasma trap crossing through the substrate zone 5.

FIG. 12 shows a cross section of a cluster plasma source, an embodiment of the present invention where two individual cathodic plasma sources, 1a and 1b, are arranged facing each other in an essentially parallel manner together with a surface 3 in an essentially triangular position. The magnetic arrays 20a and 20b form a closed loop magnetic traps 9 over the respective target elements 2a and 2b. The target elements 2a and 2b have in this case a cylindrical form, and are intended, or though not necessarily have, to rotate while the magnetic arrays are essentially static. The magnetic polarity of the arrays are such that an area of substantial very low magnetic field is generated in between the two plasma sources and guiding magnetic field lines 8 form channels for the electron escape 4. Surface 3 would be negatively biased either by external means of by a self-bias induced by the plasma. In addition shields 10a-b and 10c-d would block potential areas of plasma discharge in competition with zones 9. It is intended that lines 8 mark the main plasma escape path 4 crossing the substrate area 5.

FIG. 13 shows a cross section of a cluster plasma source as described by previous FIGS. 1-4 of the present invention. In this particular example two individual cathodic plasma sources, 1a and 1b, are arranged facing each other in an essentially parallel manner. The magnetic polarity of the arrays 20a and 20b is such that an area of substantial very low magnetic field is generated in between the two plasma sources and guiding magnetic field lines 8 form channels for electron escape 4. The cluster also includes a surface 3 which is negatively biased either by external means or by self-biasing from the plasma. In addition an anodic element 11 is introduced which could, or could not, have a magnetic array 12 in such a way that the electric field generated by the positively biased element 11 and the magnetic link established with the plasma cluster would guide the electrons from the plasma cluster towards the anode. In that way the plasma would cross the substrate zone 5 providing also guidance for the positive particles which follow the electrons.

FIG. 14 shows a cross section of a cluster plasma source as described by previous FIGS. 7-9 and FIG. 12 of the present invention. In this particular example two individual cylindrical cathodic plasma sources, 1a and 1b, are arranged facing each other in an essentially parallel manner. The magnetic polarity of the arrays 20a and 20b is such that an area of substantial very low magnetic field is generated in between the two plasma sources and guiding magnetic field lines 8 form channels for electron escape 4. The cluster also includes a surface 3 which is negatively biased either by external means or by self-biasing from the plasma. In addition an anodic element 11 is introduced which could, or could not, have a magnetic array 12 in such a way that the electric field generated by the positively biased element 11 and the magnetic link established with the plasma cluster would guide the electrons from the plasma cluster towards the anode. In that way, the plasma would cross the substrate zone 5 providing also guidance for the positive particles which follow the electrons.

The invention is not restricted to the details of the foregoing embodiments, which are merely exemplary of the invention. In particular, different combinations of plasma source units, surfaces, materials of construction, biasing etc., could be used without departing from the scope of the invention.

1. A plasma source comprising: a first and a second, spaced-apart plasma source unit each plasma source unit comprising a target and a magnetic means; wherein the magnetic means each create a magnetic field which forms a closed loop magnetic trap over their respective targets; and which fields interact to form: an area of substantially very low magnetic field strength in a region located between the plasma sources; and a guiding magnetic field extending away from the region located between the plasma source units.

2. The plasma source of claim 1, further comprising means for electrically biasing the plasma source units.

3. The plasma source of claim 2, wherein the electrical bias is any one or more of the group comprising: DC; pulsed DC; AC at 1 to a few hundred Hz; kHz AC or pulsed DC; MHz AC or pulsed DC; HIPIMS; combined discharge modes; and arc plasma discharge mode.

4. The plasma source of claim 2 or claim 3, wherein the electrical bias is applied between the plasma source units, or between the plasma source units and a supplementary anode/cathode.

5. The plasma source of any of claims 2 to 4, wherein the closed-loop magnetic trap comprises a magnetic field that is substantially perpendicular to the electric field.

6. The plasma source of any of claims 2 to 5, wherein the channel is substantially perpendicular to the electric field.

7. The plasma source of any preceding claim, wherein the target comprises a consumable target.

8. The plasma source of any preceding claim, wherein the target is located adjacent to the magnetic means.

9. The plasma source of any preceding claim, wherein the target comprises a block of consumable material fixed relative to the magnetic means.

10. The plasma source of any of claims 1 to 9, wherein the target comprises a tubular target.

11. The plasma source of claim 10, wherein the target comprises a tubular target arranged to surround the magnetic means.

12. The plasma source of any of claim 9 or 10, wherein the tubular target is mounted for rotation about the magnetic means.

13. The plasma source of any of preceding claim, wherein the polarities of the magnetic means of first and a second plasma source units are arranged in opposition.

14. The plasma source of any of preceding claim, wherein the magnetic means comprises a magnet or a group of magnets.

15. The plasma source of any of preceding claim, wherein the magnet or magnets are permanent magnets and/or electromagnets.

16. The plasma source of any of preceding claim, wherein the magnet or magnets of each plasma source unit form a magnetic field that can be represented by magnetic field lines that intersect the target at spaced apart locations, but which curve away from the target to form the closed-loop magnetic trap or traps.

17. The plasma source of any of preceding claim, wherein the magnetic fields of the plasma source units interact and can be represented by magnetic field lines that extend outwardly from the targets and away from the region located between the plasma source units to form the channel.

18. The plasma source of any of preceding claim, wherein the channel comprises a volume of relatively low magnetic field strength, which poses little resistance to the flow of ions within the plasma to create a path of least resistance along which ions of the plasma preferentially flow, in use.

19. The plasma source of any of preceding claim, wherein the plasma source units are inclined relative to one another to create a bias such that, in use, the plasma is preferentially ejected from one side of the source.

20. The plasma source of any of preceding claim, comprising three plasma source units.

21. The plasma source of claim 20, wherein the three plasma source units are arranged in a U shape, such that the magnetic fields interact with one another to form a single channel extending outwardly from the open part of the U.

22. The plasma source of any of any of claims 1 to 19 comprising a pair of plasma source units and a surface.

23. The plasma source of claim 22, wherein the surface is located at, or on one side of the pair of plasma source units to form a U-shape, such that the surface and magnetic fields of the plasma source units interact to form a single channel extending outwardly from the open part of the U.

24. The plasma source of claim 22 or claim 23, wherein the surface is in contact with, or integrally formed with, one or both of the magnetic means.

25. The plasma source of any of claims 22 to 24, wherein surface is electrically biased relative to the magnetic means.

26. The plasma source of any of claims 22 to 25, wherein the surface is any one or more of the group comprising: negatively biased by an external potential; negatively self-biased by the plasma; biased at substantially the same potential as target or targets; and at a floating self-biased potential.

27. The plasma source of any of claims 1 to 24, wherein the surface comprises an electrically insulated component.

28. A vacuum processing apparatus comprising a plasma source according to any preceding claim.

29. The vacuum processing apparatus of claim 28, further comprising means for forming a controlled atmosphere around the plasma source, the controlled atmosphere comprising any one or more of the group comprising: a vacuum; a partial vacuum; an inert gas; and a reactive gas.

30. The vacuum processing apparatus of claim 28 or claim 29, further comprising a substrate zone within a process chamber of the apparatus, wherein at least one channel of the plasma source extends over the substrate zone, in use.

31. The vacuum processing apparatus of claims 28 to 30, further comprising a supplementary anode and/or a supplementary magnet for guiding, in use, the electrons of the plasma over the substrate.

32. The vacuum processing apparatus of any of claims 28 to 31, further comprising one or more shields arranged, in use, to block potential areas of plasma discharge.

33. A web, glass, display, decorative or batch coater according to any of claims 28 to 32.

34. A plasma source of any of the preceding claims or used in any of the preceding claims where the plasma discharge is mainly in arc mode in at least one of the plasma sources

35. A plasma source of any of the proceeding claims where at least a magnetron sputtering source or any other PVD sourced is also used.
